(19) United States
(12) Patent Application Publication
(10) Pub. No.: US 2024/0410948 A1
(43) Pub. Date: Dec. 12, 2024

(54) Systems And Methods For Providing Battery Usage

(71) Applicant: Chevron U.S.A. Inc., San Ramon, CA (US)

(72) Inventor: Matthew Scott Bolen, The Woodlands, TX (US)

(21) Appl. No.: 18/331,115

(22) Filed: Jun. 7, 2023

(51) Int. Cl. G01R 31/367; G01R 31/36

(52) U.S. Cl. CPC G01R 31/367; G01R 31/3648

(57) ABSTRACT

The invention relates generally to systems and methods for generating a predictive model for predicting outcomes related to battery usage and battery replacement. The predictive model can be associated with a software application or server.

### FIELD OF THE DISCLOSURE

The present disclosure relates to systems and methods for delivering power.

### BACKGROUND

Power grids are a conventional way of delivering power to homes and businesses. However, they are often susceptible to weaknesses and failures such as blackouts and brownouts. Thus, many people desire individual sources of power such as personal generators. But personal generators are often difficult to use and maintain, resulting in high costs and frustration for the user. These and other deficiencies exist. Therefore, there is a need to provide an invention that overcomes these deficiencies and makes it easier for consumers to swap, recharge, and share individual power sources.

### SUMMARY OF THE DISCLOSURE

In some aspects, the techniques described herein relate to a system including: a battery processor configured to generate a first battery datum associated with a battery, wherein the battery processor is further configured to transmit the battery datum to merchant processor; a first user processor; and a merchant processor configured to: receive, from the battery processor, a first battery datum associated with a first battery; generate a predictive model based on the first battery datum, wherein the predictive model is configured to predict one or more outcomes associated with the battery; train the predictive model across one or more iterations; update, by the processor, the predictive model with one or more new battery datum; generate, by the predictive model, the one or more outcomes associated with the battery; and transmit an order inquiry to a first user processor, wherein the order inquiry is responsive to the one or more outcomes generated by the predictive model.

In some aspects, the techniques described herein relate to a method including: receiving, from a battery processor, a first battery datum associated with a first battery; generating a predictive model based on the battery datum, wherein the predictive model is configured to predict one or more outcomes associated with the battery; training the predictive model across one or more iterations; updating, by the processor, the predictive model with one or more new battery datum; generating, by the predictive model, one or more outcomes associated with the battery; and transmitting an order inquiry to a first user processor, wherein the order inquiry is responsive to the one or more outcomes generated by the predictive model.

In some aspects, the techniques described herein relate to a computer readable non-transitory medium including computer executable instructions that, when executed on a processor, configure the processor to perform procedures including the steps of: receiving, from a battery processor, a first battery datum associated with a first battery; generating a predictive model based on the battery datum, wherein the predictive model is configured to predict one or more outcomes associated with the battery; training the predictive model across one or more iterations; updating, by the processor, the predictive model with one or more new battery datum; generating, by the predictive model, one or more outcomes associated with the battery; and transmitting an order inquiry to a first user processor, wherein the order inquiry is transmitted in response to the one or more outcome generated by the predictive model.

Further features of the disclosed systems and methods, and the advantages offered thereby, are explained in greater detail hereinafter with reference to specific example embodiments illustrated in the accompanying drawings.

### BRIEF DESCRIPTION OF THE DRAWINGS

In order to facilitate a fuller understanding of the present invention, reference is now made to the attached drawings. The drawings should not be construed as limiting the present invention, but are intended only to illustrate different aspects and embodiments of the invention.

FIG. 1 illustrates a system according to an exemplary embodiment.

FIG. 2 illustrates a method according to an exemplary embodiment.

FIG. 3 illustrates a method according to an exemplary embodiment.

FIG. 4 illustrates a method according to an exemplary embodiment.

FIG. 5 illustrates a method according to an exemplary embodiment.

FIG. 6 illustrates a neural network according to an exemplary embodiment.

FIG. 7 illustrates a method according to an exemplary embodiment.

### DETAILED DESCRIPTION

Exemplary embodiments of the invention will now be described in order to illustrate various features of the invention. The embodiments described herein are not intended to be limiting as to the scope of the invention, but rather are intended to provide examples of the components, use, and operation of the invention.

Furthermore, the described features, advantages, and characteristics of the embodiments may be combined in any suitable manner. One skilled in the relevant art will recognize that the embodiments may be practiced without one or more of the specific features or advantages of an embodiment. In other instances, additional features and advantages may be recognized in certain embodiments that may not be present in all embodiments.

The flowchart and block diagrams in the Figures illustrate the architecture, functionality, and operation of possible implementations of systems, methods, and computer program products according to various embodiments of the present invention. In this regard, each block in the flowchart or block diagrams may represent a module, segment, or portion of instructions, which comprises one or more executable instructions for implementing the specified logical function(s). In some alternative implementations, the functions noted in the block may occur out of the order noted in the figures. For example, two blocks shown in succession may, in fact, be executed substantially concurrently, or the blocks may sometimes be executed in the reverse order, depending upon the functionality involved. It will also be noted that each block of the block diagrams and/or flowchart illustration, and combinations of blocks in the block diagrams and/or flowchart illustration, can be implemented by special purpose hardware-based systems that perform the specified functions or acts or carry out combinations of special purpose hardware and computer instructions.

The invention relates generally to systems and methods for facilitating orders for personal use batteries used for powering homes, abodes, vehicles, or any entity using batteries. The system generally employs one or more battery processors, one or more user processors, one or more merchant processors, and one or more servers and/or server processors. The system works in at least the following way: observe battery levels or predict power needs, generate a suggestion to one or more users based on those battery levels or predicted power needs, transmit the suggestion to one or more users, and transmit an order confirmation. In other embodiments, the system can facilitate a sharing of batteries or chargers among multiple users. The system uses the predictive model and/or neural network to calculate demand, supply, and pricing.

These systems and methods solve the problem among conventional personal generators or personal batteries which do not employ battery processor in communication with user devices or user processors, merchant processors, and server processors. Furthermore, there are no existing systems and methods that employ predictive models, artificial intelligence, or neural networks that generate suggestions and pricing based on battery usage, battery life, weather information, and other power usage data. The present embodiments offer a solution to this problem, giving users a quicker and more efficient way of managing their personal generators and batteries. More specifically, these systems and methods reduce the friction between users and merchants regarding battery usage, disposal, recharging, delivery, and pricing. These systems and methods also enable a processor to perform an unconventional and novel process of using predictive modeling to generate suggestions regarding battery usage.

Although the present embodiments make reference to uses at home residences, it is understood that the systems and methods described herein can be applied to without limitation industrial and commercial operations, oil and gas operations, and power grid reliability systems. The system's ability to observe battery levels or predict power needs can be highly beneficial in industrial or commercial settings where a consistent and reliable power supply is crucial. By accurately estimating power demands, the system can optimize battery usage, reduce downtime, and ensure uninterrupted operations. The predictive models and neural networks employed by the system can help businesses in industrial or commercial operations better understand the demand and supply dynamics of batteries. This information can be used to optimize inventory management, ensure sufficient battery availability, and avoid shortages or excesses. The system's ability to facilitate battery or charger sharing among multiple users can be particularly valuable in industrial or commercial settings. It enables the efficient allocation of batteries across different devices or equipment, ensuring optimal utilization and reducing the need for excessive battery inventory. By leveraging the system's automated ordering and confirmation process, industrial or commercial operations can streamline their battery procurement process. This eliminates manual and time-consuming tasks associated with placing orders, tracking deliveries, and managing inventory, leading to improved operational efficiency. The system's use of predictive models and artificial intelligence for calculating pricing based on battery usage and other factors can help industrial or commercial users optimize their costs. By providing accurate pricing estimates and suggesting efficient battery usage patterns, businesses can make informed decisions and minimize unnecessary expenses. The system's ability to collect and analyze data related to battery usage, battery life, weather information, and power usage can provide valuable insights for industrial or commercial operations. These insights can be used for proactive maintenance planning, identifying power consumption patterns, and optimizing overall energy management strategies.

These systems may also be valuable in oil and gas applications. Oil and gas operations often involve remote and off-grid locations where reliable power supply is crucial. The system's ability to monitor battery levels or predict power needs can aid in remote power monitoring and management. It can provide real-time insights into battery status, allowing operators to proactively address any potential power supply issues and minimize downtime. Furthermore, oil and gas operations often involve a wide range of equipment and machinery that require power sources. The system's ability to suggest efficient battery usage patterns can aid in optimizing power allocation. It can analyze the power demands of different equipment, predict their usage patterns, and recommend the most effective allocations of batteries to ensure reliable power supply across the operation. In other embodiments, oil and gas operations require strict adherence to safety regulations and environmental standards. The system's ability to generate suggestions based on battery usage and weather information can help operators make informed decisions that prioritize safety and environmental considerations. For example, it can recommend battery charging or replacement schedules to minimize the risk of hazardous situations or optimize energy efficiency.

Furthermore, the systems and methods described herein could be applied to general power grid reliability systems. For example, the system's ability to observe battery levels or predict power needs can be extended to monitor the load on the power grid. By analyzing historical data and considering factors such as weather conditions, usage patterns, and demand fluctuations, the system can predict future load requirements. This information can be used to proactively manage the power grid and ensure adequate supply to meet demand, reducing the risk of blackouts or brownouts. Furthermore, the predictive models and neural networks employed by the system can aid in grid balancing and peak shaving strategies. By analyzing demand patterns and predicting peak demand periods, the system can suggest battery usage and dispatch strategies to reduce strain on the power grid during high-demand periods. This helps prevent overloading, improves grid stability, and minimizes the need for additional power generation capacity. The data collected and analyzed by the system, including battery usage, weather information, and power consumption patterns, can provide valuable insights for grid planning and optimization. By utilizing this information, grid operators can make informed decisions regarding infrastructure upgrades, capacity planning, and resource allocation, leading to a more reliable and resilient power grid.

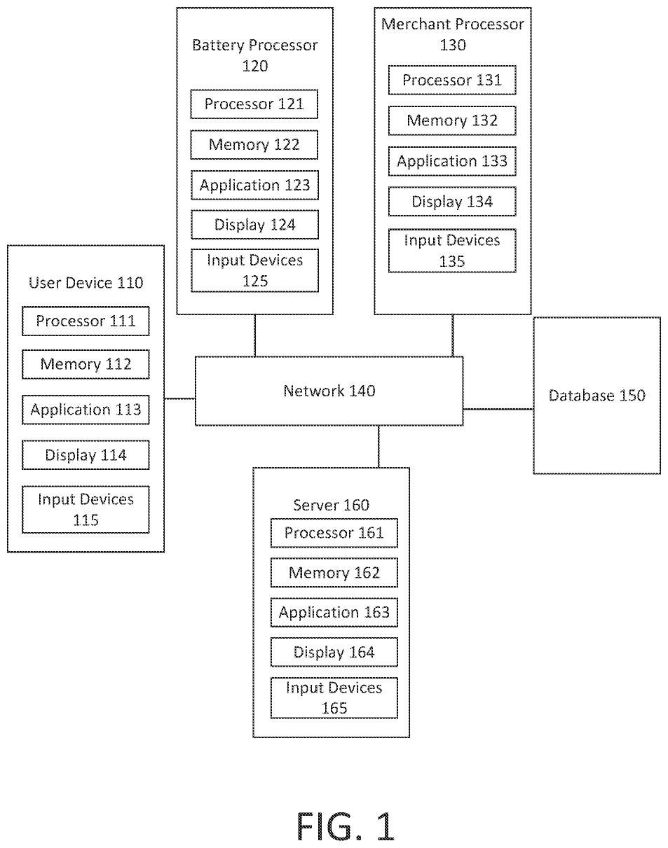

FIG. 1 illustrates a system 100 according to an exemplary embodiment. The system 100 may comprise a user device 110, a battery processor 120, a merchant processor 130, a network 140, a database 150, and a server 160. Although FIG. 1 illustrates single instances of components of system 100, system 100 may include any number of components.

System 100 may include a user device 110. The user device 110 may be a network-enabled computer device. Exemplary network-enabled computer devices include, without limitation, a server, a network appliance, a personal computer, a workstation, a phone, a handheld personal computer, a personal digital assistant, a thin client, a fat client, an Internet browser, a mobile device, a kiosk, or other a computer device or communications device. For example, network-enabled computer devices may include an iPhone, iPod, iPad from Apple® or any other mobile device running Apple's iOS® operating system, any device running Microsoft's Windows® Mobile operating system, any device running Google's Android® operating system, and/or any other smartphone, tablet, or like wearable mobile device. A wearable smart device can include without limitation a smart watch.

The user device 110 may include a processor 111, a memory 112, and an application 113. The processor 111 may be a processor, a microprocessor, or other processor, and the user device 110 may include one or more of these processors. The processor 111 may include processing circuitry, which may contain additional components, including additional processors, memories, error and parity/CRC checkers, data encoders, anti-collision algorithms, controllers, command decoders, security primitives and tamper-proofing hardware, as necessary to perform the functions described herein.

The processor 111 may be coupled to the memory 112. The memory 112 may be a read-only memory, write-once read-multiple memory or read/write memory, e.g., RAM, ROM, and EEPROM, and the user device 110 may include one or more of these memories. A read-only memory may be factory programmable as read-only or one-time programmable. One-time programmability provides the opportunity to write once then read many times. A write-once read-multiple memory may be programmed at one point in time. Once the memory is programmed, it may not be rewritten, but it may be read many times. A read/write memory may be programmed and re-programed many times after leaving the factory. It may also be read many times. The memory 112 may be configured to store one or more software applications, such as the application 113, and other data, such as user's private data and financial account information.

The application 113 may comprise one or more software applications, such as a mobile application and a web browser, comprising instructions for execution on the user device 110. In some examples, the user device 110 may execute one or more applications, such as software applications, that enable, for example, network communications with one or more components of the system 100, transmit and/or receive data, and perform the functions described herein. Upon execution by the processor 111, the application 113 may provide the functions described in this specification, specifically to execute and perform the steps and functions in the process flows described below. Such processes may be implemented in software, such as software modules, for execution by computers or other machines. The application 113 may provide graphical user interfaces (GUIs) through which a user may view and interact with other components and devices within the system 100. The GUIs may be formatted, for example, as web pages in HyperText Markup Language (HTML), Extensible Markup Language (XML) or in any other suitable form for presentation on a display device depending upon applications used by users to interact with the system 100.

The user device 110 may further include a display 114 and input devices 115. The display 114 may be any type of device for presenting visual information such as a computer monitor, a flat panel display, and a mobile device screen, including liquid crystal displays, light-emitting diode displays, plasma panels, and cathode ray tube displays. The input devices 115 may include any device for entering information into the user device 110 that is available and supported by the user device 110, such as a touch-screen, keyboard, mouse, cursor-control device, touch-screen, microphone, digital camera, video recorder or camcorder. These devices may be used to enter information and interact with the software and other devices described herein.

System 100 may include a battery processor 120. The battery processor 120 may be a network-enabled computer device. Exemplary network-enabled computer devices include, without limitation, a server, a network appliance, a personal computer, a workstation, a phone, a handheld personal computer, a personal digital assistant, a thin client, a fat client, an Internet browser, a mobile device, a kiosk, a contactless card, an automatic teller machine (ATM), or other a computer device or communications device. For example, network-enabled computer devices may include an iPhone, iPod, iPad from Apple® or any other mobile device running Apple's iOS® operating system, any device running Microsoft's Windows® Mobile operating system, any device running Google's Android® operating system, and/or any other smartphone, tablet, or like wearable mobile device. A wearable smart device can include without limitation a smart watch.

The battery processor 120 may include a processor 121, a memory 122, and an application 123. The processor 121 may be a processor, a microprocessor, or other processor, and the battery processor 120 may include one or more of these processors. The processor 121 may include processing circuitry, which may contain additional components, including additional processors, memories, error and parity/CRC checkers, data encoders, anti-collision algorithms, controllers, command decoders, security primitives and tamper-proofing hardware, as necessary to perform the functions described herein.

The processor 121 may be coupled to the memory 122. The memory 122 may be a read-only memory, write-once read-multiple memory or read/write memory, e.g., RAM, ROM, and EEPROM, and the battery processor 120 may include one or more of these memories. A read-only memory may be factory programmable as read-only or one-time programmable. One-time programmability provides the opportunity to write once then read many times. A write-once read-multiple memory may be programmed at one point in time. Once the memory is programmed, it may not be rewritten, but it may be read many times. A read/write memory may be programmed and re-programed many times after leaving the factory. It may also be read many times. The memory 122 may be configured to store one or more software applications, such as the application 123, and other data, such as user's private data and financial account information.

The application 123 may comprise one or more software applications, such as a mobile application and a web browser, comprising instructions for execution on the battery processor 120. In some examples, the battery processor 120 may execute one or more applications, such as software applications, that enable, for example, network communications with one or more components of the system 100, transmit and/or receive data, and perform the functions described herein. Upon execution by the processor 121, the application 123 may provide the functions described in this specification, specifically to execute and perform the steps and functions in the process flows described below. Such processes may be implemented in software, such as software modules, for execution by computers or other machines. The application 123 may provide graphical user interfaces (GUIs) through which a user may view and interact with other components and devices within the system 100. The GUIs may be formatted, for example, as web pages in HyperText Markup Language (HTML), Extensible Markup Language (XML) or in any other suitable form for presentation on a display device depending upon applications used by users to interact with the system 100.

The battery processor 120 may further include a display 124 and input devices 125. The display 124 may be any type of device for presenting visual information such as a computer monitor, a flat panel display, and a mobile device screen, including liquid crystal displays, light-emitting diode displays, plasma panels, and cathode ray tube displays. The input devices 125 may include any device for entering information into the battery processor 120 that is available and supported by the battery processor 120, such as a touch-screen, keyboard, mouse, cursor-control device, touch-screen, microphone, digital camera, video recorder or camcorder. These devices may be used to enter information and interact with the software and other devices described herein.

System 100 may include a merchant processor 130. The merchant processor 130 may be a network-enabled computer device. Exemplary network-enabled computer devices include, without limitation, a server, a network appliance, a personal computer, a workstation, a phone, a handheld personal computer, a personal digital assistant, a thin client, a fat client, an Internet browser, a mobile device, a kiosk, a contactless card, an automatic teller machine (ATM), or other a computer device or communications device. For example, network-enabled computer devices may include an iPhone, iPod, iPad from Apple® or any other mobile device running Apple's iOS® operating system, any device running Microsoft's Windows® Mobile operating system, any device running Google's Android® operating system, and/or any other smartphone, tablet, or like wearable mobile device.

The merchant processor 130 may include a processor 131, a memory 132, and an application 133. The processor 131 may be a processor, a microprocessor, or other processor, and the merchant processor 130 may include one or more of these processors. The processor 131 may include processing circuitry, which may contain additional components, including additional processors, memories, error and parity/CRC checkers, data encoders, anti-collision algorithms, controllers, command decoders, security primitives and tamper-proofing hardware, as necessary to perform the functions described herein.

The processor 131 may be coupled to the memory 132. The memory 132 may be a read-only memory, write-once read-multiple memory or read/write memory, e.g., RAM, ROM, and EEPROM, and the merchant processor 130 may include one or more of these memories. A read-only memory may be factory programmable as read-only or one-time programmable. One-time programmability provides the opportunity to write once then read many times. A write-once read-multiple memory may be programmed at a point in time after the memory chip has left the factory. Once the memory is programmed, it may not be rewritten, but it may be read many times. A read/write memory may be programmed and re-programed many times after leaving the factory. It may also be read many times. The memory 132 may be configured to store one or more software applications, such as the application 133, and other data, such as user's private data and financial account information.

The application 133 may comprise one or more software applications comprising instructions for execution on the merchant processor 130. In some examples, the merchant processor 130 may execute one or more applications, such as software applications, that enable, for example, network communications with one or more components of the system 100, transmit and/or receive data, and perform the functions described herein. Upon execution by the processor 131, the application 133 may provide the functions described in this specification, specifically to execute and perform the steps and functions in the process flows described below. Such processes may be implemented in software, such as software modules, for execution by computers or other machines. The application 133 may provide GUIs through which a user may view and interact with other components and devices within the system 100. The GUIs may be formatted, for example, as web pages in HyperText Markup Language (HTML), Extensible Markup Language (XML) or in any other suitable form for presentation on a display device depending upon applications used by users to interact with the system 100.

The merchant processor 130 may further include a display 134 and input devices 135. The display 134 may be any type of device for presenting visual information such as a computer monitor, a flat panel display, and a mobile device screen, including liquid crystal displays, light-emitting diode displays, plasma panels, and cathode ray tube displays. The input devices 135 may include any device for entering information into the merchant processor 130 that can be available and supported by the merchant processor 130, such as a touch-screen, keyboard, mouse, cursor-control device, touch-screen, microphone, digital camera, video recorder or camcorder. These devices may be used to enter information and interact with the software and other devices described herein.

System 100 may include one or more networks 140. In some examples, the network 140 may be one or more of a wireless network, a wired network or any combination of wireless network and wired network, and may be configured to connect the user device 110, the battery processor 120, the merchant processor 130, the database 150 and the server 160. For example, the network 140 may include one or more of a fiber optics network, a passive optical network, a cable network, an Internet network, a satellite network, a wireless local area network (LAN), a Global System for Mobile Communication, a Personal Communication Service, a Personal Area Network, Wireless Application Protocol, Multimedia Messaging Service, Enhanced Messaging Service, Short Message Service, Time Division Multiplexing based systems, Code Division Multiple Access based systems, D-AMPS, Wi-Fi, Fixed Wireless Data, IEEE 802.11b, 802.15.1, 802.11n and 802.11g, Bluetooth, NFC, Radio Frequency Identification (RFID), Wi-Fi, and/or the like.

In addition, the network 140 may include, without limitation, telephone lines, fiber optics, IEEE Ethernet 902.3, a wide area network, a wireless personal area network, a LAN, or a global network such as the Internet. In addition, the network 140 may support an Internet network, a wireless communication network, a cellular network, or the like, or any combination thereof. The network 140 may further include one network, or any number of the exemplary types of networks mentioned above, operating as a stand-alone network or in cooperation with each other. The network 140 may utilize one or more protocols of one or more network elements to which they are communicatively coupled. The network 140 may translate to or from other protocols to one or more protocols of network devices. Although the network 140 is depicted as a single network, it should be appreciated that according to one or more examples, the network 140 may comprise a plurality of interconnected networks, such as, for example, the Internet, a service provider's network, a cable television network, corporate networks, such as credit card association networks, and home networks. The network 140 may further comprise, or be configured to create, one or more front channels, which may be publicly accessible and through which communications may be observable, and one or more secured back channels, which may not be publicly accessible and through which communications may not be observable.

System 100 may include a database 150. The database 150 may be one or more databases configured to store data, including without limitation, private data of users, financial accounts of users, identities of users, transactions of users, and certified and uncertified documents. The database 150 may comprise a relational database, a non-relational database, or other database implementations, and any combination thereof, including a plurality of relational databases and non-relational databases. In some examples, the database 150 may comprise a desktop database, a mobile database, or an in-memory database. Further, the database 150 may be hosted internally by the server 160 or may be hosted externally of the server 160, such as by a server, by a cloud-based platform, or in any storage device that is in data communication with the server 160.

The server 160 may be a network-enabled computer device. Exemplary network-enabled computer devices include, without limitation, a server, a network appliance, a personal computer, a workstation, a phone, a handheld personal computer, a personal digital assistant, a thin client, a fat client, an Internet browser, a mobile device, a kiosk, a contactless card, an automatic teller machine (ATM), or other a computer device or communications device. For example, network-enabled computer devices may include an iPhone, iPod, iPad from Apple® or any other mobile device running Apple's iOS® operating system, any device running Microsoft's Windows® Mobile operating system, any device running Google's Android® operating system, and/or any other smartphone, tablet, or like wearable mobile device.

The server 160 may include a processor 161, a memory 162, and an application 163. The processor 161 may be a processor, a microprocessor, or other processor, and the server 160 may include one or more of these processors. The server 160 can be onsite, offsite, standalone, networked, online, or offline.

The processor 161 may include processing circuitry, which may contain additional components, including additional processors, memories, error and parity/CRC checkers, data encoders, anti-collision algorithms, controllers, command decoders, security primitives and tamper-proofing hardware, as necessary to perform the functions described herein.

The processor 161 may be coupled to the memory 162. The memory 162 may be a read-only memory, write-once read-multiple memory or read/write memory, e.g., RAM, ROM, and EEPROM, and the server 160 may include one or more of these memories. A read-only memory may be factory programmable as read-only or one-time programmable. One-time programmability provides the opportunity to write once then read many times. A write-once read-multiple memory may be programmed at a point in time after the memory chip has left the factory. Once the memory is programmed, it may not be rewritten, but it may be read many times. A read/write memory may be programmed and re-programed many times after leaving the factory. It may also be read many times. The memory 162 may be configured to store one or more software applications, such as the application 163, and other data, such as user's private data and financial account information.

The application 163 may comprise one or more software applications comprising instructions for execution on the server 160. In some examples, the server 160 may execute one or more applications, such as software applications, that enable, for example, network communications with one or more components of the system 100, transmit and/or receive data, and perform the functions described herein. Upon execution by the processor 161, the application 163 may provide the functions described in this specification, specifically to execute and perform the steps and functions in the process flows described below. Such processes may be implemented in software, such as software modules, for execution by computers or other machines. The application 163 may provide GUIs through which a user may view and interact with other components and devices within the system 100. The GUIs may be formatted, for example, as web pages in HyperText Markup Language (HTML), Extensible Markup Language (XML) or in any other suitable form for presentation on a display device depending upon applications used by users to interact with the system 100.

The server 160 may further include a display 164 and input devices 165. The display 164 may be any type of device for presenting visual information such as a computer monitor, a flat panel display, and a mobile device screen, including liquid crystal displays, light-emitting diode displays, plasma panels, and cathode ray tube displays. The input devices 165 may include any device for entering information into the merchant processor 130 that is available and supported by the merchant processor 130, such as a touch-screen, keyboard, mouse, cursor-control device, touch-screen, microphone, digital camera, video recorder or camcorder. These devices may be used to enter information and interact with the software and other devices described herein.

In some examples, exemplary procedures in accordance with the present disclosure described herein can be performed by a processing arrangement and/or a computing arrangement (e.g., a computer hardware arrangement). Such processing/computing arrangement can be, for example entirely or a part of, or include, but not limited to, a computer/processor that can include, for example one or more microprocessors, and use instructions stored on a non-transitory computer-accessible medium (e.g., RAM, ROM, hard drive, or other storage device). For example, a computer-accessible medium can be part of the memory of the user device 110, the battery processor 120, the merchant processor 130, the network 140, the database 150, and the server 160 or other computer hardware arrangement.

In some examples, a computer-accessible medium (e.g., as described herein, a storage device such as a hard disk, floppy disk, memory stick, CD-ROM, RAM, ROM, etc., or a collection thereof) can be provided (e.g., in communication with the processing arrangement). The computer-accessible medium can contain executable instructions thereon. In addition or alternatively, a storage arrangement can be provided separately from the computer-accessible medium, which can provide the instructions to the processing arrangement so as to configure the processing arrangement to execute certain exemplary procedures, processes, and methods, as described herein above, for example.

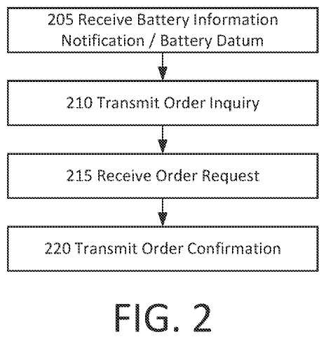

FIG. 2 is a method diagram illustrating a method according to an exemplary embodiments. The method can include without limitation a battery processor, a user device or some processor associated with a user, a merchant processor, a server, and a data storage unit. These elements are discussed with further reference to FIG. 1. As a nonlimiting embodiment, the battery processor can be associated with one or more batteries used for power usage in a home, vehicle, abode, community, or some other use. For example, the battery processor may be associated with a battery being used as a personal power source for a home. The battery processor can track information associated with the battery, including without limitation battery life, battery usage, battery degradation, or anticipated battery life. The merchant processor can be associated with a third party who buys, sells, maintains, manufactures, or otherwise deals in batteries for personal or commercial sale or use. The merchant processor may be in communication with the battery processor and the user device. As a nonlimiting example, the user device can include a software application or web application associated with the merchant processor. The user device can download the application, thus giving a means of communication between the user device, the battery processor, and the merchant processor. Furthermore, the merchant processor can be associated with a server and a data storage unit or database. The data storage unit can be used for long term storage, i.e. separate from RAM or ROM in a typical computer. The merchant processor and server may be in communication with the data storage unit for the purposes of storing and retrieving data related to the battery, the user, and other data described herein.

In action 205, the merchant processor can receive a battery information notification from the battery processor. This notification can include various data associated with the battery, including without limitation battery levels, battery life or degradation, or disposal. In other embodiments, the battery information notification can simply include the desire to replace or recharge a certain battery. In other embodiments, other kinds of information can be received via a power usage notification or anticipated power usage notification. In other embodiments, the battery information notification can be sent from the battery processor to the user device, then to the merchant processor. In still other embodiments, the battery information notification can be sent from the battery processor to a server, then to the merchant processor and/or user device. The information can be sent over a wireless network discussed with further reference to FIG. 1. Once the merchant process has received the battery information notification, the merchant processor in action 210 can transmit an order inquiry to the user device associated with the battery processor. The merchant processor can, based on the battery information notification, determine which user device is associated with the particular battery processor or processors. For example, the battery processor may transmit user identification information or some serial number. The merchant processor can determine if such information can be matched with a user on file. In other embodiments, these actions can be performed by a server. In still other embodiments, these actions can include retrieving user information such as an address and contact information from the data storage unit. An order inquiry can include a message or prompt inquiring whether the user would like one or more services associated with the battery, including without limitation: replacing a battery; recharging a battery; disposing or carrying away a defective, dead, or otherwise spent battery; transporting one or more additional batteries; picking up a battery and bringing it to a different user. The order inquiry can include one or more options including at least the services described herein. The order inquiry can be configured such that the inquiry can be responded to be a user device, user device application, or web application. In action 215, the merchant processor can receive an order request from the user device. The order request can be responsive to the order inquiry. Pursuant to the order request, the merchant processor in action 220 can transmit an order confirmation including at least a message that the user's order has been confirmed. Other information can include date, time, and location information regarding the order. In other embodiments, the order request can be further processed and/or stored in the server before being transmitted to the merchant processor.

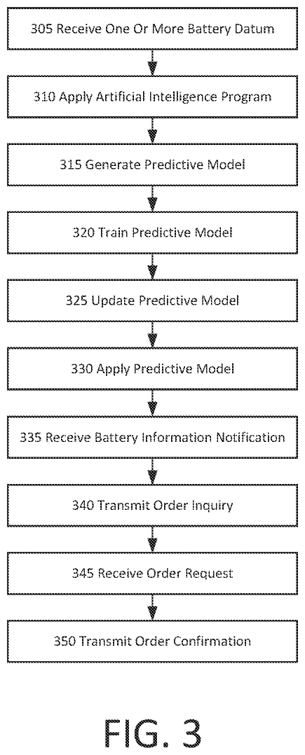

FIG. 3 is a method diagram illustrating a method according to an exemplary embodiment for generating a predictive model for determining a most appropriate order inquiry. The method can include without limitation a battery processor, a user device or some processor associated with a user, a merchant processor, a server, and a data storage unit. These elements are discussed with further reference to FIG. 1. As a nonlimiting embodiment, the battery processor can be associated with one or more batteries used for power usage in a home, vehicle, abode, community, or some other use. For example, the battery processor may be associated with a battery being used as a personal power source for a home. The battery processor can track information associated with the battery, including without limitation battery life, battery usage, battery degradation, or anticipated battery life. The merchant processor can be associated with a third party who buys, sells, maintains, manufactures, or otherwise deals in batteries for personal or commercial sale or use. The merchant processor may be in communication with the battery processor and the user device. As a nonlimiting example, the user device can include a software application or web application associated with the merchant processor. The user device can download the application, thus giving a means of communication between the user device, the battery processor, and the merchant processor. Furthermore, the merchant processor can be associated with a server and a data storage unit or database. The data storage unit can be used for long term storage, i.e. separate from RAM or ROM in a typical computer. The merchant processor and server may be in communication with the data storage unit for the purposes of storing and retrieving data related to the battery, the user, and other data described herein.

In action 305, the merchant processor can receive one or more user datum over a wireless network from the battery processor, the user device, or some other processor including the server. The network is discussed with further reference to FIG. 1. In the event of a power outage or other event that limits access to power, the merchant processor may receive data over a cellular network or any other suitable network for receiving data. This notification can include various data associated with the battery, including without limitation battery levels, battery life or degradation, or disposal. In other embodiments, the battery information notification can simply include the desire to replace or recharge a certain battery. In other embodiments, other kinds of information can be received via a power usage notification or anticipated power usage notification. In other embodiments, the battery information notification can be sent from the battery processor to the user device, then to the merchant processor. In still other embodiments, the battery information notification can be sent from the battery processor to a server, then to the merchant processor and/or user device. The information can be sent over a wireless network discussed with further reference to FIG. 1.

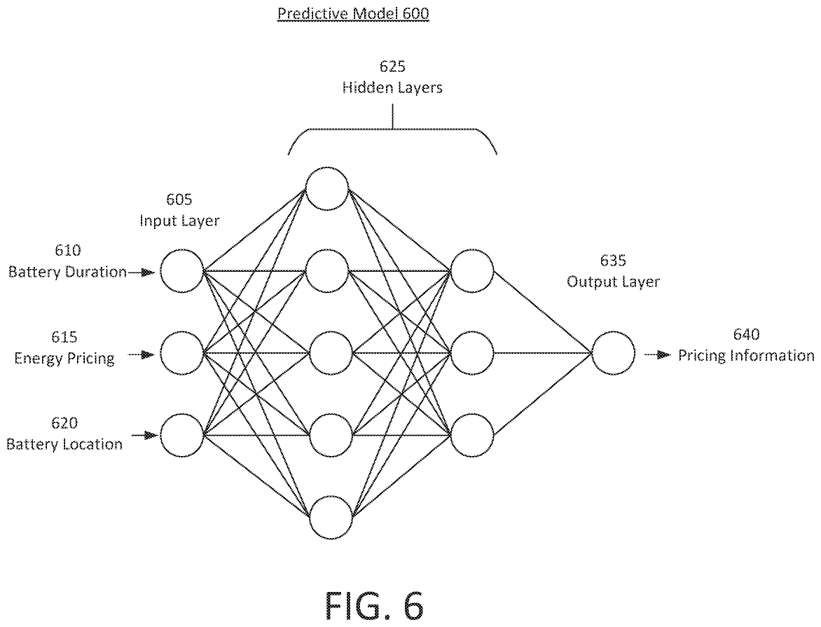

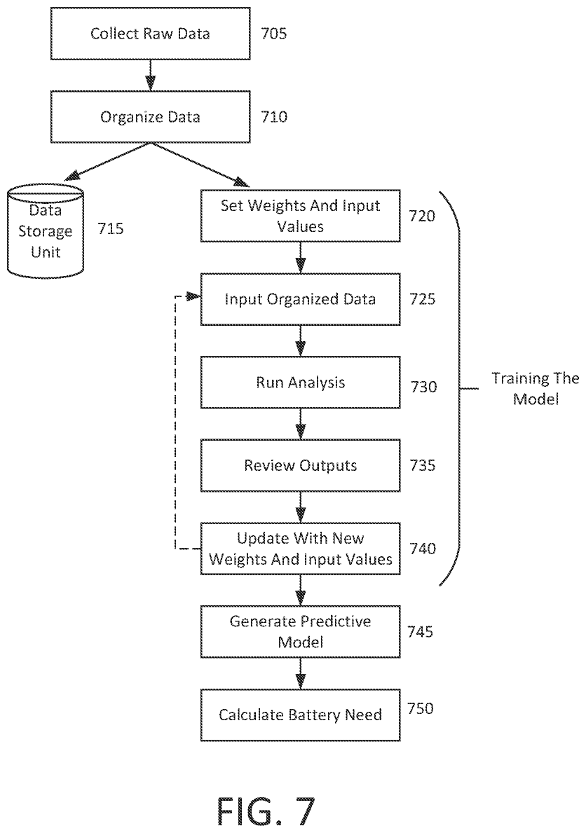

In action 310, an artificial intelligence program can be applied to the one or more user datum. This action can be performed by the merchant processor which can be configured to apply the artificial intelligence program. In other embodiments, the merchant processor can transmit the one or more user datum to the server at which point the server can apply the artificial intelligence program. In other embodiments, neural networks or machine learning can be applied. Artificial intelligence, neural networks, and machine learning are discussed with further reference to FIG. 6. In action 315, the merchant processor or server can generate a predictive model based on the user datum received. In some embodiments, the predictive model can also be fed past and/or historical data regarding the battery or some other data described herein. In action 320, the predictive model can be trained with further reference to FIGS. 6 and 7. Next, the predictive model can be updated with further reference to FIGS. 6 and 7. In action 325, the predictive model can be updated through one or more iterations with new data as well as historical data that had not yet been considered. Once the predictive model (herein referred to at other points as artificial intelligence, machine learning, or neural networks) has been generated, trained, and updated, in action 330 the predictive model can be applied to one or more additional user datum. For example, the predictive model can be applied to the one or more user datum from action 305. The predictive model can be trained to figure out one or more things, including without limitation: battery pricing; battery supply; battery replacement; specific order inquiries; and other needs specific to one or more customers or customer populations. Other purposes for the predictive model are discussed with further reference to FIGS. 6 and 7.

Once the merchant process has received the battery information notification, the merchant processor in action 340 can transmit an order inquiry to the user device associated with the battery processor. The merchant processor can, based on the battery information notification, determine which user device is associated with the particular battery processor or processors. For example, the battery processor may transmit user identification information or some serial number. The merchant processor can determine if such information can be matched with a user on file. In other embodiments, these actions can be performed by a server. In still other embodiments, these actions can include retrieving user information such as an address and contact information from the data storage unit. An order inquiry can include a message or prompt inquiring whether the user would like one or more services associated with the battery, including without limitation: replacing a battery; recharging a battery; disposing or carrying away a defective, dead, or otherwise spent battery; transporting one or more additional batteries; picking up a battery and bringing it to a different user. The order inquiry can include one or more options including at least the services described herein. The order inquiry can be configured such that the inquiry can be responded to be a user device, user device application, or web application. In action 345, the merchant processor can receive an order request from the user device. The order request can be responsive to the order inquiry. Pursuant to the order request, the merchant processor in action 350 can transmit an order confirmation including at least a message that the user's order has been confirmed. Other information can include date, time, and location information regarding the order. In other embodiments, the order request can be further processed and/or stored in the server before being transmitted to the merchant processor.

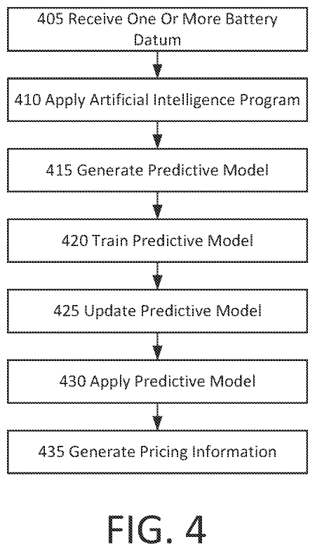

FIG. 4 is a method diagram illustrating a method according to an exemplary embodiment for generating a predictive model for determining a most appropriate order inquiry. The method can include without limitation a battery processor, a user device or some processor associated with a user, a merchant processor, a server, and a data storage unit. These elements are discussed with further reference to FIG. 1. As a nonlimiting embodiment, the battery processor can be associated with one or more batteries used for power usage in a home, vehicle, abode, community, or some other use. For example, the battery processor may be associated with a battery being used as a personal power source for a home. The battery processor can track information associated with the battery, including without limitation battery life, battery usage, battery degradation, or anticipated battery life. The merchant processor can be associated with a third party who buys, sells, maintains, manufactures, or otherwise deals in batteries for personal or commercial sale or use. The merchant processor may be in communication with the battery processor and the user device. As a nonlimiting example, the user device can include a software application or web application associated with the merchant processor. The user device can download the application, thus giving a means of communication between the user device, the battery processor, and the merchant processor. Furthermore, the merchant processor can be associated with a server and a data storage unit or database. The data storage unit can be used for long term storage, i.e. separate from RAM or ROM in a typical computer. The merchant processor and server may be in communication with the data storage unit for the purposes of storing and retrieving data related to the battery, the user, and other data described herein.

In action 405, the merchant processor can receive one or more user datum over a wireless network from the battery processor, the user device, or some other processor including the server. This notification can include various data associated with the battery, including without limitation battery levels, battery life or degradation, or disposal. In other embodiments, the battery information notification can simply include the desire to replace or recharge a certain battery. In other embodiments, other kinds of information can be received via a power usage notification or anticipated power usage notification. In other embodiments, the battery information notification can be sent from the battery processor to the user device, then to the merchant processor. In still other embodiments, the battery information notification can be sent from the battery processor to a server, then to the merchant processor and/or user device. The information can be sent over a wireless network discussed with further reference to FIG. 1.

In action 410, an artificial intelligence program can be applied to the one or more user datum. This action can be performed by the merchant processor which can be configured to apply the artificial intelligence program. In other embodiments, the merchant processor can transmit the one or more user datum to the server at which point the server can apply the artificial intelligence program. In other embodiments, neural networks or machine learning can be applied. Artificial intelligence, neural networks, and machine learning are discussed with further reference to FIG. 6. In action 415, the merchant processor or server can generate a predictive model based on the user datum received. In some embodiments, the predictive model can also be fed past and/or historical data regarding the battery or some other data described herein. In action 420, the predictive model can be trained with further reference to FIGS. 6 and 7. Next, the predictive model can be updated with further reference to FIGS. 6 and 7. In action 325, the predictive model can be updated through one or more iterations with new data as well as historical data that had not yet been considered. Once the predictive model (herein referred to at other points as artificial intelligence, machine learning, or neural networks) has been generated, trained, and updated, in action 430 the predictive model can be applied to one or more additional user datum. For example, the predictive model can be applied to the one or more user datum from action 405. The predictive model can be trained to figure out one or more things, including without limitation: battery pricing; battery supply; battery replacement; specific order inquiries; and other needs specific to one or more customers or customer populations. Other purposes for the predictive model are discussed with further reference to FIGS. 6 and 7. For example, in action 435, the predictive model can generate pricing information. Pricing information can change according to the parameters of the predictive model, including time, place, weather, needs of one or more other users, as well as other factors.

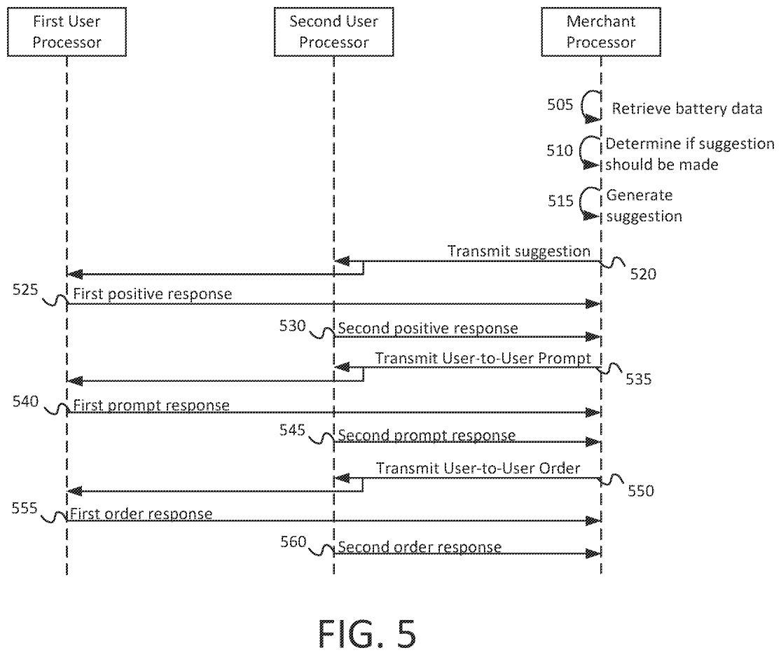

FIG. 5 is a chart illustrating a process according to an exemplary embodiment. The process can include without limitation a first user processor, a second user processor, and a merchant processor. In other embodiments, it is understood that additional user processors can be included. The user processors can be associated with the user devices discussed with further reference to FIG. 1. Furthermore, the merchant processor can be associated with a third party who buys, sells, maintains, manufactures, or otherwise deals in batteries for personal or commercial sale or use. The merchant processor may be in communication with the battery processor and the user device. As a nonlimiting example, the user device can include a software application or web application associated with the merchant processor. The user device can download the application, thus giving a means of communication between the user device, the battery processor, and the merchant processor. Furthermore, the merchant processor can be associated with a server and a data storage unit or database. The data storage unit can be used for long term storage, i.e. separate from RAM or ROM in a typical computer. The merchant processor and server may be in communication with the data storage unit for the purposes of storing and retrieving data related to the battery, the user, and other data described herein.

In action 505, the merchant processor can receive one or more battery data. The battery data can include various data associated with the battery, including without limitation battery levels, battery life or degradation, or disposal. In other embodiments, the battery information notification can simply include the desire to replace or recharge a certain battery. In other embodiments, other kinds of information can be received via a power usage notification or anticipated power usage notification. In other embodiments, the battery information notification can be sent from the battery processor to the user device, then to the merchant processor. In still other embodiments, the battery information notification can be sent from the battery processor to a server, then to the merchant processor and/or user device. The information can be sent over a wireless network discussed with further reference to FIG. 1.

In action 510 the merchant processor can determine if a suggestion should be made, generated, and otherwise created for the purpose of being sent to the first and second user processors. The determination can include figuring out whether the first and second user have enough battery power, need a battery replacement, or have some other desire or need associated with their battery. This determination can be made by the merchant processor through one or more predictive models, neural networks, or machine learning algorithms discussed with further reference to FIGS. 3, 4, 6, and 7. If the processor determines that a suggestion should be made, then in action 515 a suggestion will be generated. In action 520 the merchant processor can transmit the suggestion to the first and second user processor over a wireless network. The user processors can receive and view the suggestion via their respective user devices. In some embodiments, the first and second user processor can be associated with one or more software applications further associated with the merchant processor. That is, the users can access the suggestion through a software application such as a user device application or web application. In actions 525 and 530, a first and second positive response can be transmitted from the first use processor and the second user processor respectively. The responses can be transmitted to the merchant processor, a server, or some other processor. The responses can be transmitted over one or more wireless networks. Each response can include one or more datum or information optionally responsive to the suggestion from action 520. For example, the responses can include various data associated with the battery, including without limitation battery levels, battery life or degradation, or disposal. In other embodiments, the battery information notification can simply include the desire to replace or recharge a certain battery. In action 535, the merchant processor or server can transmit a user-to-user prompt to the first and second user processors respectively. The user-to-user prompt can include without limitation a prompt or message allowing the first and second users to agree to some user-to-user order. This user-to-user order can include an order to give or share one or more goods or services related to each user's battery, battery power, battery usage, or recharging capabilities. As a nonlimiting example, the user-to-user prompt can include a message facilitating the sharing of a battery from the first user to the second user. In response to the user-to-user prompt, in actions 540 and 545 the merchant processor or server can receive a first prompt response from the first user processor and a second user prompt from the second user processor. Each response can include an indication that a respective user is agreeing to a user-to-user order. In other embodiments, more users and user processors can be involved in a user-to-user prompt. In action 550, the merchant processor or server can transmit a user-to-user order in response to the one or more prompt responses. The user-to-user order can be sent to each of the user processors that sent a prompt response. Nonresponding parties may be omitted from the user-to-user order. In response to the user-to-user order, the first user processor can transmit a first order response, and in action 560 the second user processor can transmit a second order response. Having completed the order responses, the agreed upon order can be facilitated by the first and second users in order to satisfy their battery needs. In other embodiments, the real-world completion of the user-to-user order can be memorialized or recorded by the users via the web or user applications through the user processors. The responses to the suggestions and to the user-to-user prompt can be recorded, stored, and used for later analysis by the predictive model with further reference to FIGS. 3, 4, 6, and 7.

A neural network is a series of algorithms that can, under predetermined training restrictions, recognize relationships between one or more variables. A neuron in a neural network is a mathematical function that collects and classifies information according to a specific form set by a user. Generally, a neural network can be divided into three main components: an input layer, a processing or hidden layer, and an output layer. The input layer comprises data sets chosen to be inserted into the neural network for analysis. The hidden layers include one or more neurons that can classify the inputs according to parameters set by the user. The hidden layers can comprise multiple successive layers, the first layer positioned immediately after the input layer and the last layer positioned immediately before the output layer. The hidden layer immediately after the input layer may be connected to the input layer via a predetermined weight or emphasis. These weights can be assigned according to the modeler's agenda. Alternatively, the model itself can determine the optimal weights between layers such that a predetermined outcome, margin of error, or minimum data point is achieved.

FIG. 6 describes a predictive model which can comprise a neural network 600. The neural network may be integrated into the server, the user device, or some other computer device suitable for neural network analysis. The neural network can include generally an input layer 605, one or more hidden layers 625, and an output layer 635. Although only a certain number of nodes are depicted in FIG. 6, it is understood that the neural network according to the disclosed embodiments may include less or more nodes in each layer. Additionally, the hidden layers can include more or less layers than what is depicted in FIG. 6. It is also understood that the connections between each layer may be assigned a predetermined weight according to user's manual change or according to some weight value generated by the neural network itself. The input layer may include sets of data gathered from outside sources. The neural network can include lease information including battery duration 610, energy pricing 615, and battery location 620. Other inputs not depicted in FIG. 6 may also comprise inputs such as historical information related to the battery, battery power, battery location, battery distribution across a certain geographic area, other geographic data associated with the users, weather information, historical energy use data, and other information. The neurons associated with the hidden layers can be trained or provisioned to classify the inputs according to parameters set by the user. As a nonlimiting example, the user can train the hidden layer to associate a higher lease price with a greater guarantee amount. As another example, the hidden layer can be trained to associate a certain battery location—for example, in Arlington, Virginia—with a guarantee amount that matches guarantee amounts found elsewhere in the location. Upon analyzing the inputs via the one or more hidden layers, the neural network can create an output or pricing information 640. It is understood that the neural network can be provisioned to create other outputs such as predicted battery usage, predicted user-to-user needs and orders, predicted grid failure, and other similar predictions related to battery needs. It is understood that one or more neural networks or some combination of neural networks can be trained according to individual battery owners, applicants within a certain geographic limit, income limit, age limit, or applicants associated with a certain historical use of the batteries.

The exemplary system, method and computer-readable medium can then apply the generated models to calculate a most efficient battery pricing or other needs associated with a battery user.

The predictive models described herein can utilize a Bidirectional Encoder Representations from Transformers (BERT) models. BERT models utilize use multiple layers of so called “attention mechanisms” to process textual data and make predictions. These attention mechanisms effectively allow the BERT model to learn and assign more importance to words from the text input that are more important in making whatever inference is trying to be made.

The exemplary system, method and computer-readable medium can utilize various neural networks, such as convolutional neural networks (CNNs) or recurrent neural networks (RNNs), to generate the exemplary models. A CNN can include one or more convolutional layers (e.g., often with a subsampling step) and then followed by one or more fully connected layers as in a standard multilayer neural network. CNNs can utilize local connections, and can have tied weights followed by some form of pooling which can result in translation invariant features.

A RNN is a class of artificial neural network where connections between nodes form a directed graph along a sequence. This facilitates the determination of temporal dynamic behavior for a time sequence. Unlike feedforward neural networks, RNNs can use their internal state (e.g., memory) to process sequences of inputs. A RNN can generally refer to two broad classes of networks with a similar general structure, where one is finite impulse and the other is infinite impulse. Both classes of networks exhibit temporal dynamic behavior. A finite impulse recurrent network can be, or can include, a directed acyclic graph that can be unrolled and replaced with a strictly feedforward neural network, while an infinite impulse recurrent network can be, or can include, a directed cyclic graph that may not be unrolled. Both finite impulse and infinite impulse recurrent networks can have additional stored state, and the storage can be under the direct control of the neural network. The storage can also be replaced by another network or graph, which can incorporate time delays or can have feedback loops. Such controlled states can be referred to as gated state or gated memory, and can be part of long short-term memory networks (LSTMs) and gated recurrent units.

RNNs can be similar to a network of neuron-like nodes organized into successive “layers,” each node in a given layer being connected with a directed e.g., (one-way) connection to every other node in the next successive layer. Each node (e.g., neuron) can have a time-varying real-valued activation. Each connection (e.g., synapse) can have a modifiable real-valued weight. Nodes can either be (i) input nodes (e.g., receiving data from outside the network), (ii) output nodes (e.g., yielding results), or (iii) hidden nodes (e.g., that can modify the data en route from input to output). RNNs can accept an input vector x and give an output vector y. However, the output vectors are based not only by the input just provided in, but also on the entire history of inputs that have been provided in in the past.

For supervised learning in discrete time settings, sequences of real-valued input vectors can arrive at the input nodes, one vector at a time. At any given time step, each non-input unit can compute its current activation (e.g., result) as a nonlinear function of the weighted sum of the activations of all units that connect to it. Supervisor-given target activations can be supplied for some output units at certain time steps. For example, if the input sequence is a speech signal corresponding to a spoken digit, the final target output at the end of the sequence can be a label classifying the digit. In reinforcement learning settings, no teacher provides target signals. Instead, a fitness function, or reward function, can be used to evaluate the RNNs performance, which can influence its input stream through output units connected to actuators that can affect the environment. Each sequence can produce an error as the sum of the deviations of all target signals from the corresponding activations computed by the network. For a training set of numerous sequences, the total error can be the sum of the errors of all individual sequences.

The models described herein may be trained on one or more training datasets, each of which may comprise one or more types of data. In some examples, the training datasets may comprise previously-collected data, such as data collected from previous uses of the same type of systems described herein and data collected from different types of systems. In other examples, the training datasets may comprise continuously-collected data based on the current operation of the instant system and continuously-collected data from the operation of other systems. In some examples, the training dataset may include anticipated data, such as the anticipated future workloads, currently scheduled workloads, and planned future workloads, for the instant system and/or other systems. In other examples, the training datasets can include previous predictions for the instant system and other types of system, and may further include results data indicative of the accuracy of the previous predictions. In accordance with these examples, the predictive models described herein may be training prior to use and the training may continue with updated data sets that reflect additional information.

FIG. 7 describes the training process for an exemplary predictive model or neural network suitable for predicting and calculating a coverage amount associated with a lease-applicant. The process can begin with action 705 when raw data is collected. The raw data can be associated with the battery itself, the battery user, and the merchant processor or server. The information can further include information related to the battery, battery power, battery location, battery distribution across a certain geographic area, other geographic data associated with the users, weather information, historical energy use data, and other information. The collection of raw data can be performed by a processor or application associated with the user device or server. The raw data can be transmitted over a wired or wireless network. The data may have been previously gathered and stored in a database or data storage unit in which case the processor or application can retrieve the data from the data storage unit. At action 710, the processor or application can organize the raw data into discernable categories including but not limited to battery type, battery usage, weather data, battery user data, and user property data. The categories can be predetermined by the user or created by the predictive model. At action 715, the organized or raw data can be transmitted to the data storage unit. The data storage unit can be associated with the user device or server. The raw or organized data can be transmitted over a wired network, wireless network, or one or more express buses. Upon organizing the data into one or categories, the processor or application can proceed with training the predictive model in actions 720 through 740. Generally, the training portion can have any number of iterations. The predictive model can comprise one or more neural network described with further reference to FIG. 6.

The training portion can begin with action 720 when the weights and input values are set by the user or by the model itself. Furthermore, the weights can be the predetermined connections between the inputs and the hidden layers described with further reference to FIG. 6. The input values are the values that are fed into the neural network. The input values may be discerned by the different categories created in action 710, although other distinct input values may be discerned. The inputs can include without limitation historical information related to the battery, battery power, battery location, battery distribution across a certain geographic area, other geographic data associated with the users, weather information, historical energy use data, and other information. In action 725, the data in inputted in the neural network, and in action 730 the neural network analyzes the data according to the weights and other parameters set by the user. As a nonlimiting, example, the merchant processor may create the stipulation that no battery replacement can be less than one $100.00. In action 735, the outputs are reviewed. The outputs can include one or more coverage amounts associated with the battery user and the merchant processor, or any relevant output determined by the user. In action 740, the predictive model may be updated with new data and parameters. The new data can be collected by the processor in a similar fashion to actions 705 and 710. Though it is not necessary in this exemplary embodiment to retrain the predictive model, the predictive model can be re-trained any number times such that actions 725 through 740 are repeated until a satisfactory output is achieved or some other parameter has been met. As a nonlimiting example, the user may update the inputs with new pricing data. As another nonlimiting example, the user can adjust the weighted relationship between the input layer and the one or more hidden layers of a neural network discussed with further reference to FIG. 6. If a satisfactory output has been recorded, then in action 745 one or more predictive models can be generated. It is understood that the predictive model, once generated, can undergo further training similar to actions 720 to 745. Having generated the predictive model, in action 750 the model can calculate a pricing amount given the unique input values collected from a particular battery user and their associated peers. It is understood that the predictive model may calculate other values including without limitation battery usage, predicted user-to-user needs and orders, predicted grid failure, and other similar predictions related to battery needs.

In some aspects, the techniques described herein relate to a system including: a battery processor configured to generate one or more battery datum associated with one or more batteries, wherein the battery processor is further configured to transmit the battery datum to merchant processor; a first user processor; and a merchant processor configured to: receive, from the battery processor, a first battery datum associated with a first battery; generate a predictive model based on the first battery datum, wherein the predictive model is configured to predict one or more outcomes associated with the battery; train the predictive model across one or more iterations; update, by the processor, the predictive model with one or more new battery datum; generate, by the predictive model, the one or more outcomes associated with the battery; transmit an order inquiry to the first user processor, wherein the order inquiry is transmitted in response to the one or more outcomes generated by the predictive model.

In some aspects, the techniques described herein relate to a system, wherein the one or more outcomes includes at least one selected from the group of battery price, power outage, or future battery needs for the first user.

In some aspects, the techniques described herein relate to a system, wherein the merchant processor is further configured to: receive, in response to the order inquiry, an order request from the first user processor; transmit, in response to the order request, an order confirmation.

In some aspects, the techniques described herein relate to a system, wherein the order request includes at least one selected from the group of a battery replacement, battery recharge, or battery swap.

In some aspects, the techniques described herein relate to a system, wherein the merchant processor is further configured to retrieve historical data associated with the battery from a data storage unit.

In some aspects, the techniques described herein relate to a system, wherein the merchant processor is further configured to: receive, from the battery processor, a second battery datum associated with a second battery, wherein the second battery is further associated with a second user processor; transmit a user-to-user prompt to the first user processor and the second user processor; receive, in response to the user-to-user prompt, a first prompt response from the first user processor and a second prompt response from the second user processor; transmit a user-to-user order to the first user processor and the second user processor, wherein the user-to-user order includes at least an order to facilitate battery sharing between a first user associated with the first user processor and a second user associated with the second user processor; and receive, in response to the user-to-user order, a first order response from the first user processor and a second order response from the second user processor.

In some aspects, the techniques described herein relate to a system, wherein the predictive model is a neural network.

In some aspects, the techniques described herein relate to a system, wherein the neural network is at least one selected from the group of an RNN or CNN.

In some aspects, the techniques described herein relate to a system, wherein the merchant processor is further configured to retrieve from a data storage unit battery usage history information associated with the battery processor.

In some aspects, the techniques described herein relate to a method including: receiving, from a battery processor, a first battery datum associated with a first battery; generating a predictive model based on the battery datum, wherein the predictive model is configured to predict one or more outcomes associated with the battery; training the predictive model across one or more iterations; updating, by the processor, the predictive model with one or more new battery datum; generating, by the predictive model, one or more outcomes associated with the battery; and transmitting an order inquiry to the first user processor, wherein the order inquiry is transmitted in response to the one or more outcome generated by the predictive model.

In some aspects, the techniques described herein relate to a method, wherein the method further includes: receiving, in response to the order inquiry, an order request from the first user processor; and transmitting, in response to the order request, an order confirmation.

In some aspects, the techniques described herein relate to a method, wherein the one or more battery outcomes includes at least a battery transfer from a first user to a second user, a renewal of a battery subscription, or an onsite battery recharge.

In some aspects, the techniques described herein relate to a method, wherein the predictive model analyzes one or more inputs including at least battery duration, energy pricing, and battery location.

In some aspects, the techniques described herein relate to a method, wherein the method further includes storing the first battery datum in a data storage unit.

In some aspects, the techniques described herein relate to a method, wherein the training step further includes setting one or more weights and values on the one or more inputs.

In some aspects, the techniques described herein relate to a method, wherein the method further includes retrieving information from one or more third party applications associated with the battery history associated with the first user processor.

In some aspects, the techniques described herein relate to a method, wherein the generating of the predictive model is responsive to a determination that based on the first battery datum, the first battery requires one or more actions.

In some aspects, the techniques described herein relate to a method, wherein the generating of the predictive model is responsive to a determination that based on one or more second data, where in the second data includes at lest weather data and power outage historical data.

In some aspects, the techniques described herein relate to a method, wherein the processor is a merchant processor associated with one or more software applications.

In some aspects, the techniques described herein relate to a computer readable non-transitory medium including computer executable instructions that, when executed on a processor, configure the processor to perform procedures including the steps of: receiving, from a battery processor, a first battery datum associated with a first battery; generating a predictive model based on the battery datum, wherein the predictive model is configured to predict one or more outcomes associated with the battery; training the predictive model across one or more iterations; updating, by the processor, the predictive model with one or more new battery datum; generating, by the predictive model, one or more outcomes associated with the battery; and transmitting an order inquiry to the first user processor, wherein the order inquiry is transmitted in response to the one or more outcome generated by the predictive model.

Although embodiments of the present invention have been described herein in the context of a particular implementation in a particular environment for a particular purpose, those skilled in the art will recognize that its usefulness is not limited thereto and that the embodiments of the present invention can be beneficially implemented in other related environments for similar purposes. The invention should therefore not be limited by the above-described embodiments, method, and examples, but by all embodiments within the scope and spirit of the invention as claimed.

In the invention, various embodiments have been described with references to the accompanying drawings. It may, however, be evident that various modifications and changes may be made thereto, and additional embodiments may be implemented, without departing from the broader scope of the invention as set forth in the claims that follow. The invention and drawings are accordingly to be regarded in an illustrative rather than restrictive sense.

The invention is not to be limited in terms of the particular embodiments described herein, which are intended as illustrations of various aspects. Many modifications and variations can be made without departing from its spirit and scope. Functionally equivalent systems, processes and apparatuses within the scope of the invention, in addition to those enumerated herein, may be apparent from the representative descriptions herein. Such modifications and variations are intended to fall within the scope of the appended claims. The invention is to be limited only by the terms of the appended claims, along with the full scope of equivalents to which such representative claims are entitled.

The preceding description of exemplary embodiments provides non-limiting representative examples referencing numerals to particularly describe features and teachings of different aspects of the invention. The embodiments described should be recognized as capable of implementation separately, or in combination, with other embodiments from the description of the embodiments. A person of ordinary skill in the art reviewing the description of embodiments should be able to learn and understand the different described aspects of the invention. The description of embodiments should facilitate understanding of the invention to such an extent that other implementations, not specifically covered but within the knowledge of a person of skill in the art having read the description of embodiments, would be understood to be consistent with an application of the invention.

What is claimed is:

1. A system comprising:
a battery processor configured to generate a first battery datum associated with a battery, wherein the battery processor is further configured to transmit the battery datum to merchant processor;
a first user processor; and
a merchant processor configured to:
receive, from the battery processor, a first battery datum associated with a first battery;
generate a predictive model based on the first battery datum, wherein the predictive model is configured to predict one or more outcomes associated with the battery;
train the predictive model across one or more iterations;
update, by the processor, the predictive model with one or more new battery datum;
generate, by the predictive model, the one or more outcomes associated with the battery; and
transmit an order inquiry to a first user processor, wherein the order inquiry is responsive to the one or more outcomes generated by the predictive model.

2. The system of claim 1, wherein the one or more outcomes comprises at least one selected from the group of battery price, power outage, or future battery needs for the first user.

3. The system of claim 1, wherein the merchant processor is further configured to:
receive, in response to the order inquiry, an order request from the first user processor; and
transmit, in response to the order request, an order confirmation.

4. The system of claim 2, wherein the order inquiry comprises at least one selected from the group of a battery replacement, battery recharge, or battery swap.

5. The system of claim 1, wherein the merchant processor is further configured to retrieve historical data associated with the battery from a data storage unit.

6. The system of claim 1, wherein the merchant processor is further configured to:
receive, from the battery processor, a second battery datum associated with a second battery, wherein the second battery is further associated with a second user processor;
transmit a user-to-user prompt to the first user processor and the second user processor;
receive, in response to the user-to-user prompt, a first prompt response from the first user processor and a second prompt response from the second user processor;
transmit a user-to-user order to the first user processor and the second user processor, wherein the user-to-user order comprises at least an order to facilitate battery sharing between a first user associated with the first user processor and a second user associated with the second user processor; and
receive, in response to the user-to-user order, a first order response from the first user processor and a second order response from the second user processor.

7. The system of claim 1, wherein the predictive model is a neural network.

8. The system of claim 7, wherein the neural network is at least one selected from the group of an RNN or CNN.

9. The system of claim 1, wherein the merchant processor is further configured to retrieve from a data storage unit battery usage history information associated with the battery processor.

10. A method comprising:
receiving, from a battery processor, a first battery datum associated with a first battery;
generating a predictive model based on the battery datum, wherein the predictive model is configured to predict one or more outcomes associated with the battery;
training the predictive model across one or more iterations;
updating, by the processor, the predictive model with one or more new battery datum;
generating, by the predictive model, one or more outcomes associated with the battery; and
transmitting an order inquiry to a first user processor, wherein the order inquiry is responsive to the one or more outcomes generated by the predictive model.

11. The method of claim 10, wherein the method further comprises:
receiving, in response to the order inquiry, an order request from the first user processor; and
transmitting, in response to the order request, an order confirmation.

12. The method of claim 10, wherein the one or more battery outcomes comprises at least a battery transfer from a first user to a second user, a renewal of a battery subscription, or an onsite battery recharge.

13. The method of claim 10, wherein the predictive model analyzes one or more inputs comprising at least battery duration, energy pricing, and battery location.

14. The method of claim 10, wherein the method further comprises storing the first battery datum in a data storage unit.

15. The method of claim 10, wherein the training step further comprises setting one or more weights and values on the one or more inputs.

16. The method of claim 10, wherein the method further comprises retrieving information from one or more third party applications associated with the battery history associated with the first user processor.

17. The method of claim 10, wherein the generating of the predictive model is responsive to a determination that based on the first battery datum, the first battery requires one or more actions.

18. The method of claim 10, wherein the generating of the predictive model is responsive to a determination that based on one or more second data, where in the second data comprises at lest weather data and power outage historical data.

19. The method of claim 10, wherein the processor is a merchant processor associated with one or more software applications.

20. A computer readable non-transitory medium comprising computer executable instructions that, when executed on a processor, configure the processor to perform procedures comprising the steps of:
receiving, from a battery processor, a first battery datum associated with a first battery;
generating a predictive model based on the battery datum, wherein the predictive model is configured to predict one or more outcomes associated with the battery;
training the predictive model across one or more iterations;
updating, by the processor, the predictive model with one or more new battery datum;
generating, by the predictive model, one or more outcomes associated with the battery; and
transmitting an order inquiry to a first user processor, wherein the order inquiry is transmitted in response to the one or more outcome generated by the predictive model.
